(19) United States
(12) Patent Application Publication
(10) Pub. No.: US 2025/0015013 A1
(43) Pub. Date: Jan. 9, 2025

(54) METHOD FOR MARKING SEMICONDUCTOR CHIP, METHOD FOR MANUFACTURING SEMICONDUCTOR CHIP, AND SEMICONDUCTOR CHIP

(71) Applicant: Mitsubishi Electric Corporation, Tokyo (JP)

(72) Inventors: Hiroto MATSUBAYASHI, Tokyo (JP); Takeshi MIURA, Tokyo (JP); Shigeo YAMABE, Fukuoka (JP)

(73) Assignee: Mitsubishi Electric Corporation, Tokyo (JP)

(21) Appl. No.: 18/711,091

(22) PCT Filed: Feb. 18, 2022
(86) PCT No.: PCT/JP2022/006605

§ 371 Date: May 16, 2024

(51) Int. Cl. H01L 23/544; H01L 21/304

(52) U.S. Cl. CPC H01L 23/544; H01L 21/304; H01L 2223/5442

(57) ABSTRACT

In a method for marking a semiconductor chip (10), the semiconductor chip (10) including a semiconductor substrate (12), in the semiconductor chip (10), a recognition pattern (18) protruding from a surface (14) is formed on the surface (14) of the semiconductor substrate (12), and marking is performed by causing the recognition pattern (18) to fall by a probe needle (20).

### FIELD

The present disclosure relates to a method for marking a semiconductor chip, a method for manufacturing a semiconductor chip, and a semiconductor chip.

### BACKGROUND

There is a case where in order to identify a conforming article and a defective article of a semiconductor chip, a marking indicating defectiveness is performed for a semiconductor chip which is determined to be defective by a characteristic inspection of the semiconductor chip. PTL 1 discloses a method for performing marking in which for a semiconductor chip determined to be defective as a result of an inspection about characteristics of the semiconductor chip, a probe needle is brought into contact with a surface of a semiconductor substrate, the surface is shaved, and a scratch mark is thereby made.

### CITATION LIST

### Patent Literature

[PTL 1] JP 2006-351947 A

### SUMMARY

### Technical Problem

However, in a method disclosed in PTL 1, depending on an abrasion state of a probe needle or a surface state of a semiconductor substrate, nonuniformity of shapes of a scratch mark occurs. When nonuniformity of the shapes of the scratch mark occurs, the scratch mark becomes thin or shallow. In such a case, there is a problem that because a shape change in a marking part between times before and after marking becomes small, recognition of the scratch mark becomes difficult.

The present disclosure has been made to solve the above problems, and an object thereof is to obtain a method for marking a semiconductor chip, in which a shape change in a marking part between times before and after the marking is large and recognition of presence or absence of the marking is easy. Further, an object thereof is to obtain a method for manufacturing a semiconductor chip, the method being capable of carrying out marking in which the shape change in the marking part between times before and after the marking is large and recognition of presence or absence of the marking is easy. Further, an object thereof is to obtain a semiconductor chip, the semiconductor chip being capable of carrying out marking in which the shape change in the marking part between times before and after the marking is large and recognition of presence or absence of the marking is easy.

### Solution to Problem

A first method for marking a semiconductor chip according to the present disclosure is a method for marking a semiconductor chip for marking a semiconductor chip including a semiconductor substrate, wherein in the semiconductor chip, a recognition pattern protruding from a surface is formed on the surface of the semiconductor substrate, and marking is performed by causing the recognition pattern to fall by a probe needle.

A second method for marking a semiconductor chip according to the present disclosure is a method for marking a semiconductor chip for marking a semiconductor chip including a semiconductor substrate, wherein in the semiconductor chip, a recess portion is formed in a surface of the semiconductor substrate, and marking is performed by pushing an edge of the recess portion by a probe needle and shaving a part of the edge.

A third method for marking a semiconductor chip according to the present disclosure is a method for marking a semiconductor chip for marking a semiconductor chip including a semiconductor substrate, wherein in the semiconductor chip, a recess portion and a lid portion covering the recess portion are formed in a surface of the semiconductor substrate, and marking is performed by opening a hole in the lid portion by a probe needle.

A fourth method for marking a semiconductor chip according to the present disclosure is a method for marking a semiconductor chip for marking a semiconductor chip including a semiconductor substrate, wherein in the semiconductor chip, a recognition pattern is formed on a surface of the semiconductor substrate, the recognition pattern having a first bridge pier and a second bridge pier, which protrude from the surface, and a bar portion, which connects together upper portions of the first bridge pier and the second bridge pier, the first bridge pier is thicker than the second bridge pier, and marking is performed by detaching the second bridge pier from the surface by pushing the bar portion by a probe needle which is moved in a direction horizontal to the surface and further by rotating the recognition pattern around the first bridge pier as a center when the semiconductor chip is seen in a direction perpendicular to the surface.

In a method for manufacturing a semiconductor chip according to the invention of the present disclosure, the semiconductor chip is manufactured by using the first to fourth methods for marking a semiconductor chip described above.

A first semiconductor chip according to the disclosure includes a semiconductor substrate; and a recognition pattern protruding from a surface on the surface of the semiconductor substrate, wherein the recognition pattern is a rectangular cuboid, a direction perpendicular to the surface is set as a z direction, between two orthogonal sides in a plane of the rectangular cuboid, the plane being perpendicular to the z direction, a direction of a short side is set as an x direction, and when lengths of the rectangular cuboid in the x direction and the z direction are respectively set as X and Z, Z≥2*X.

A second semiconductor chip according to the disclosure includes a semiconductor substrate; and a first bridge pier and a second bridge pier, which protrude from a surface, and a bar portion, which connects together upper portions of the first bridge pier and the second bridge pier, on the surface of the semiconductor substrate, wherein the first bridge pier is thicker than the second bridge pier.

### Advantageous Effects of Invention

In a method for marking a semiconductor chip according to the present disclosure, marking can be carried out in which a shape change in a making part between times before and after the marking is large and recognition of presence or absence of the marking is easy. Further, in a method for manufacturing a semiconductor chip according to the present disclosure, a semiconductor chip can be obtained, the semiconductor chip being capable of carrying out marking in which the shape change in the marking part between times before and after the marking is large and recognition of presence or absence of the marking is easy. Further, a semiconductor chip according to the present disclosure can carry out marking in which the shape change in the marking part between times before and after the marking is large and recognition of presence or absence of the marking is easy.

### BRIEF DESCRIPTION OF DRAWINGS

FIG. 1 is a top view of the semiconductor chip according to the first embodiment.

FIG. 2 is a cross-sectional view the semiconductor chip according to the first embodiment.

FIG. 3 is a cross-sectional view illustrating a method for marking the semiconductor chip in the first embodiment.

FIG. 4 is a top view illustrating the semiconductor chip after marking in the first embodiment.

FIG. 5 is a cross-sectional view illustrating the semiconductor chip after marking in the first embodiment.

FIG. 6 is a top view of the semiconductor chip according to the second embodiment.

FIG. 7 is a cross-sectional view the semiconductor chip according to the second embodiment.

FIG. 8 is a cross-sectional view illustrating a method for marking the semiconductor chip in the second embodiment.

FIG. 9 is a top view illustrating the semiconductor chip after marking in the second embodiment.

FIG. 10 is a cross-sectional view illustrating the semiconductor chip after marking in the second embodiment.

FIG. 11 is a top view of the semiconductor chip according to the third embodiment.

FIG. 12 is a cross-sectional view the semiconductor chip according to the third embodiment.

FIG. 13 is a cross-sectional view illustrating a method for marking the semiconductor chip in the third embodiment.

FIG. 14 is a top view illustrating the semiconductor chip after marking in the third embodiment.

FIG. 15 is a cross-sectional view illustrating the semiconductor chip after marking in the third embodiment.

FIG. 16 is a top view of the semiconductor chip according to the fourth embodiment.

FIG. 17 is a cross-sectional view the semiconductor chip according to the fourth embodiment.

FIG. 18 is a cross-sectional view the semiconductor chip according to the fourth embodiment.

FIG. 19 is a cross-sectional view illustrating a method for marking the semiconductor chip in the fourth embodiment.

FIG. 20 is a top view illustrating the semiconductor chip after marking in the fourth embodiment.

FIG. 21 is a cross-sectional view illustrating the semiconductor chip after marking in the fourth embodiment.

FIG. 22 is a top view of the semiconductor chip according to a modification of the first embodiment.

FIG. 23 is a cross-sectional view illustrating the semiconductor chip after marking in the modification of the first embodiment.

### DESCRIPTION OF EMBODIMENTS

### First Embodiment

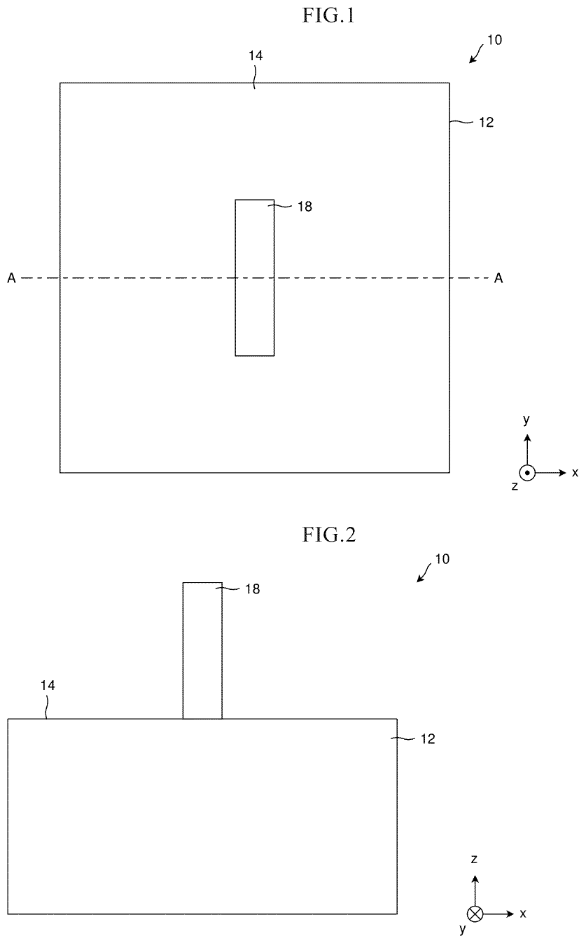

A semiconductor chip 10 according to the present embodiment is illustrated in FIG. 1 and FIG. 2. FIG. 1 is a top view of the semiconductor chip 10, and FIG. 2 is a cross-sectional view taken along line A-A in FIG. 1.

The semiconductor chip 10 functions as an optical semiconductor device, a high frequency amplification device, or the like, for example, but its functions are not limited to those. Further, circuits or the like for realizing those functions are not illustrated in the drawings.

The semiconductor chip 10 includes a semiconductor substrate 12. A recognition pattern 18 is formed on a surface 14 of the semiconductor substrate 12. The recognition pattern 18 is formed to protrude from the surface 14 of the semiconductor substrate 12. The recognition pattern 18 is a rectangular cuboid. A direction perpendicular to the surface 14 of the semiconductor substrate 12 is set as a z direction. Between two orthogonal sides in a plane of the rectangular cuboid, the plane being perpendicular to the z direction, directions of a short side and a long side are respectively set as an x direction and a y direction. When lengths of the rectangular cuboid in the x, y, and z directions are respectively set as X, Y, and Z, Y>X, and Z≥2*X. Here, an asterisk (*) is an operator for multiplication.

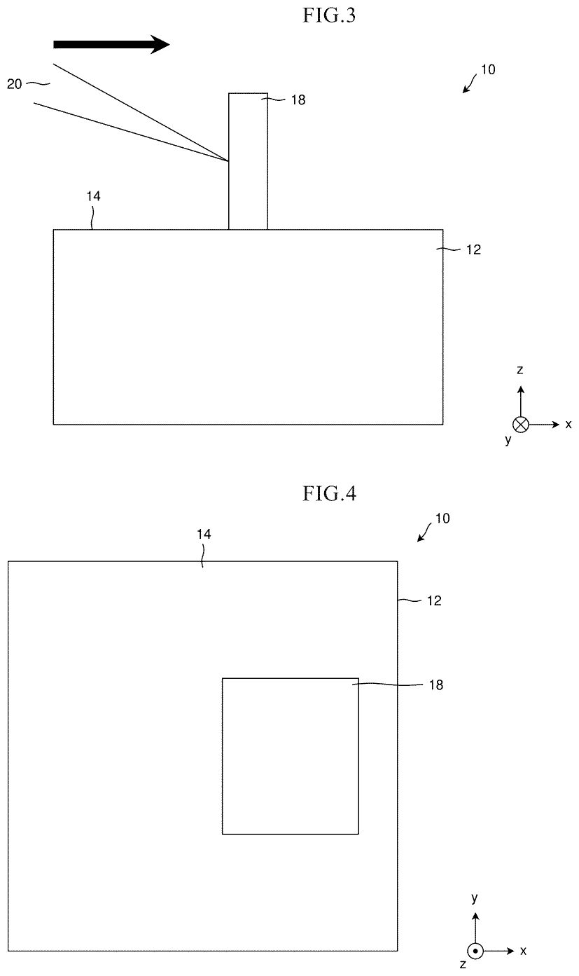

In a method for performing marking in the present embodiment, as illustrated in FIG. 3, a probe needle 20 is moved in the x direction in a state where the probe needle 20 floats above the surface 14 of the semiconductor substrate 12, the probe needle 20 pushes a side surface of the recognition pattern 18, which is perpendicular to the x direction, and causes the recognition pattern 18 to fall, and the marking is thereby performed.

A state resulting from the fall of the recognition pattern 18 is illustrated in FIG. 4 and FIG. 5. An area of the recognition pattern 18 as seen in the z direction is obtained by X*Y before the marking (FIG. 1) and is obtained by Y*Z after the marking (FIG. 4). An increase ratio of the area between times before and after the marking is expressed by (Y*Z)÷(X*Y)=Z÷X and becomes 2 or more because Z≥2*X.

When the surface 14 of the semiconductor substrate 12 is seen in the z direction, presence or absence of the marking can be identified. Because when the recognition pattern 18 has fallen, a position of the recognition pattern 18 moves in the x direction between times before and after the marking, presence or absence of the marking can be identified. Further, because the area of the recognition pattern 18 becomes two times or larger, presence or absence of the marking can be identified based on a change in a size of the recognition pattern 18.

As described above, in the method for marking the semiconductor chip according to the present embodiment, because the position of the recognition pattern moves, a shape change in a making part between times before and after the marking is large, and recognition of presence or absence of the marking is easy. The change in the size of the recognition pattern also contributes to facilitation of recognition. Further, because the marking is performed by causing the recognition pattern to fall, the marking is less likely to be influenced by an abrasion state of the probe needle and a surface state of the semiconductor substrate.

Further, position control in the z direction does not have to be highly precise. In a method for forming a scratch mark in related art, because a shape of the scratch mark is changed depending on a position of the probe needle in the z direction, the position control has to be highly precise. However, in the present embodiment, because even when the position in the z direction is somewhat changed, causing the recognition pattern to fall does not become difficult, the position control in the z direction does not have to be highly precise.

Further, when a semiconductor chip is manufactured by using the method for marking the semiconductor chip according to the present embodiment, the semiconductor chip can be obtained which provides the above effects.

### Second Embodiment

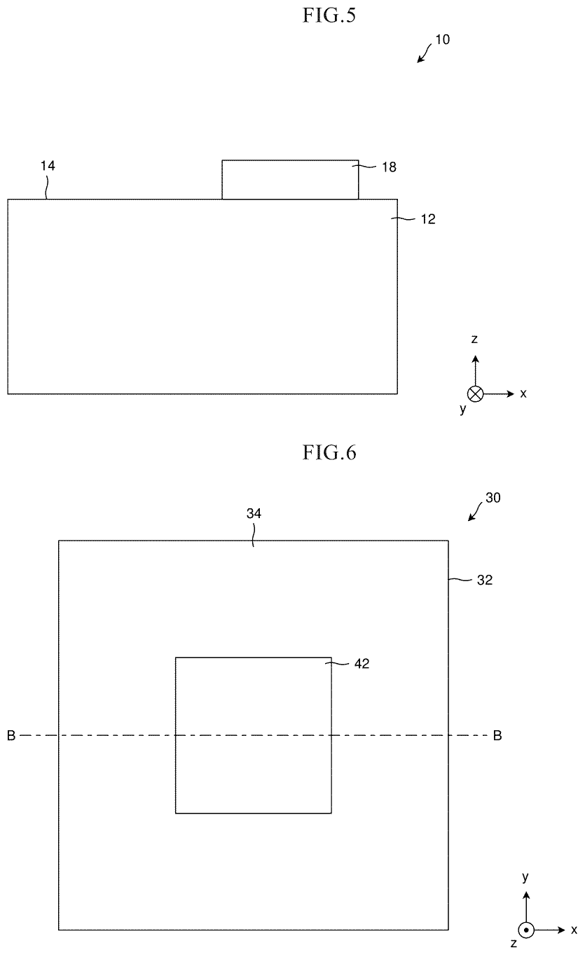

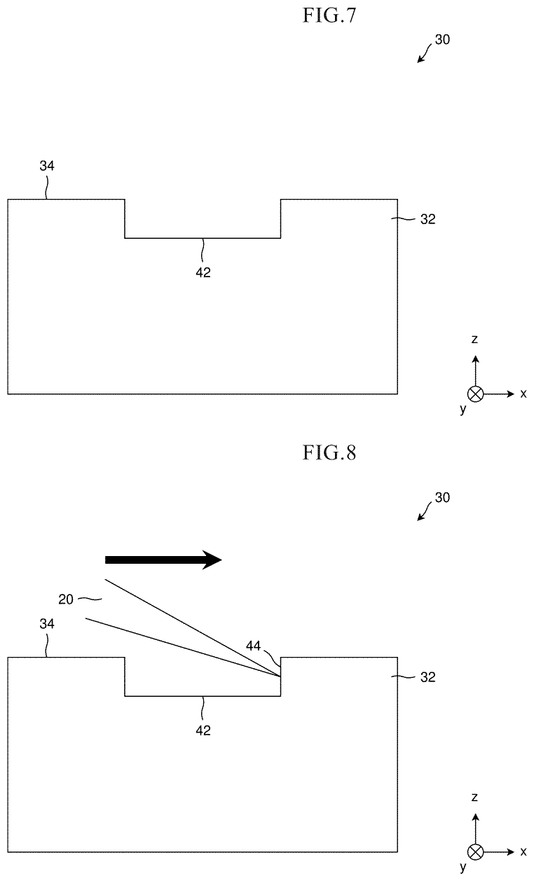

A semiconductor chip 30 according to the present embodiment is illustrated in FIG. 6 and FIG. 7. Here, differences from the first embodiment will mainly be described. FIG. 6 is a top view of the semiconductor chip 30, and FIG. 7 is a cross-sectional view taken along line B-B in FIG. 6.

A recess portion 42 is formed in a surface 34 of a semiconductor substrate 32.

In a method for performing marking in the present embodiment, an edge 44 of the recess portion 42 is pushed by the probe needle 20 as illustrated in FIG. 8, and a part of the edge 44 is shaved, and the marking is thereby performed.

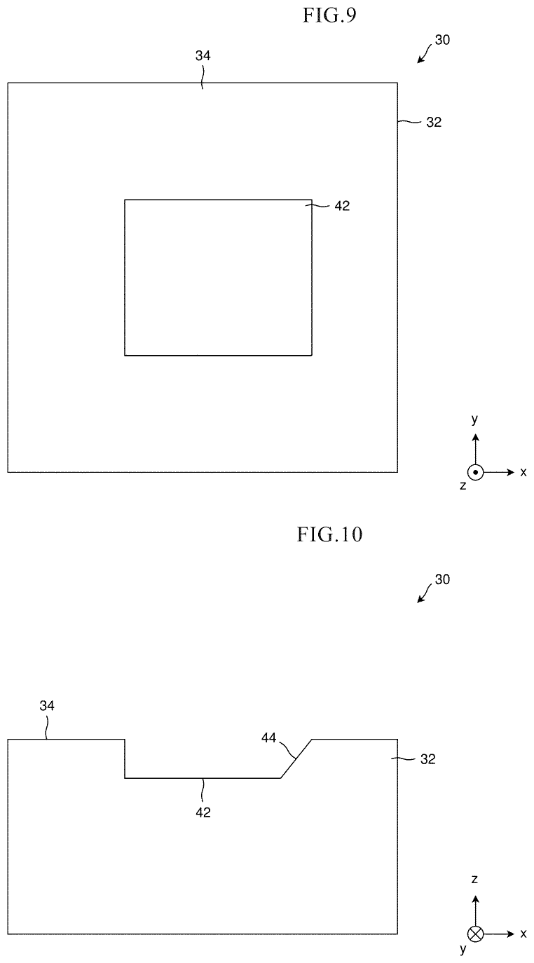

The recess portion 42 obtained after a part of the edge 44 is shaved is illustrated in FIG. 9 and FIG. 10. An area of the recess portion 42 as seen in the z direction becomes larger by an amount by which the edge 44 is shaved.

As described above, in the method for marking the semiconductor chip according to the present embodiment, because the edge of the recess portion is pushed by the probe needle, force is perpendicularly exerted on the edge. Thus, the edge of the recess portion can certainly be shaved off. Consequently, the shape change in the marking part between times before and after the marking is large, and recognition of presence or absence of the marking is easy.

Further, the position control in the z direction does not have to be highly precise. In the present embodiment, because it is sufficient that a distal end of the probe needle comes into contact with the edge of the recess portion even when the position in the z direction is somewhat changed, the position control in the z direction does not have to be highly precise.

Further, when a semiconductor chip is manufactured by using the method for marking the semiconductor chip according to the present embodiment, the semiconductor chip can be obtained which provides the above effects.

### Third Embodiment

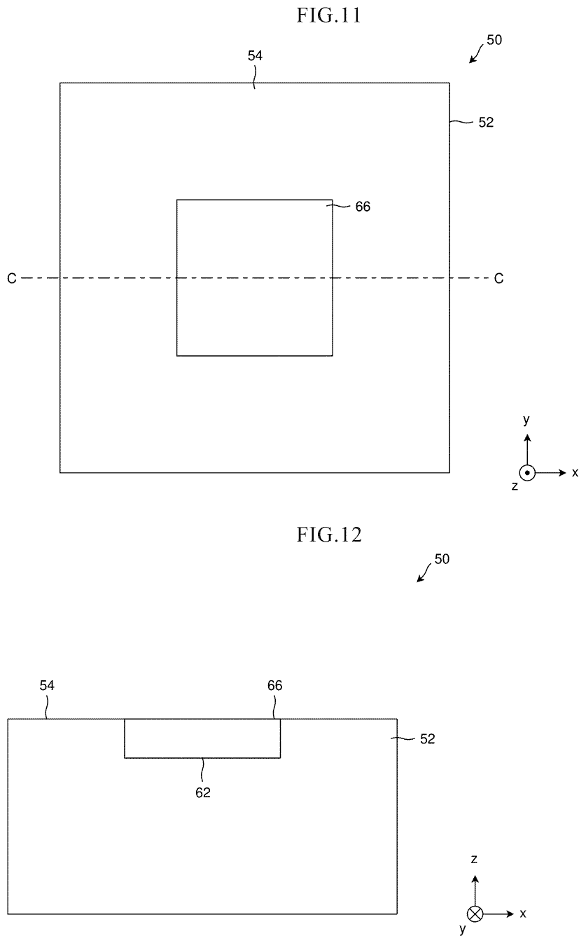

A semiconductor chip 50 according to the present embodiment is illustrated in FIG. 11 and FIG. 12. Here, differences from the first embodiment will mainly be described. FIG. 11 is a top view of the semiconductor chip 50, and FIG. 12 is a cross-sectional view taken along line C-C in FIG. 11.

In a surface 54 of a semiconductor substrate 52, a recess portion 62 and a lid portion 66 covering the recess portion 62 are formed. A cavity is formed between the recess portion 62 and the lid portion 66.

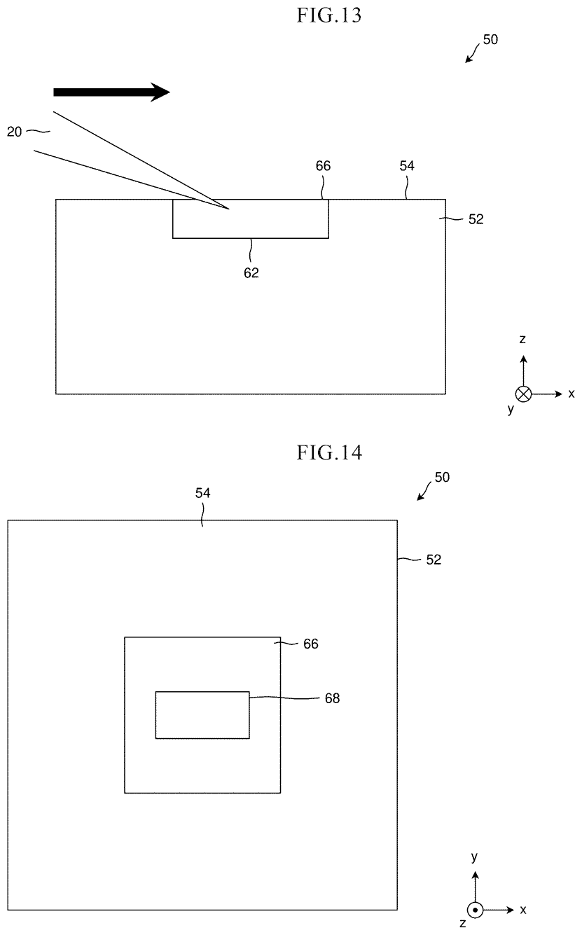

In a method for performing marking in the present embodiment, after a hole 68 is opened in the lid portion 66 by moving the probe needle 20 downward in the z direction as illustrated in FIG. 13, the probe needle 20 is moved in a direction parallel to the surface 54 of the semiconductor substrate 52, the hole 68 is expanded, and the marking is thereby performed. Note that the probe needle 20 may be moved only in the z direction without being moved in the direction parallel to the surface 54.

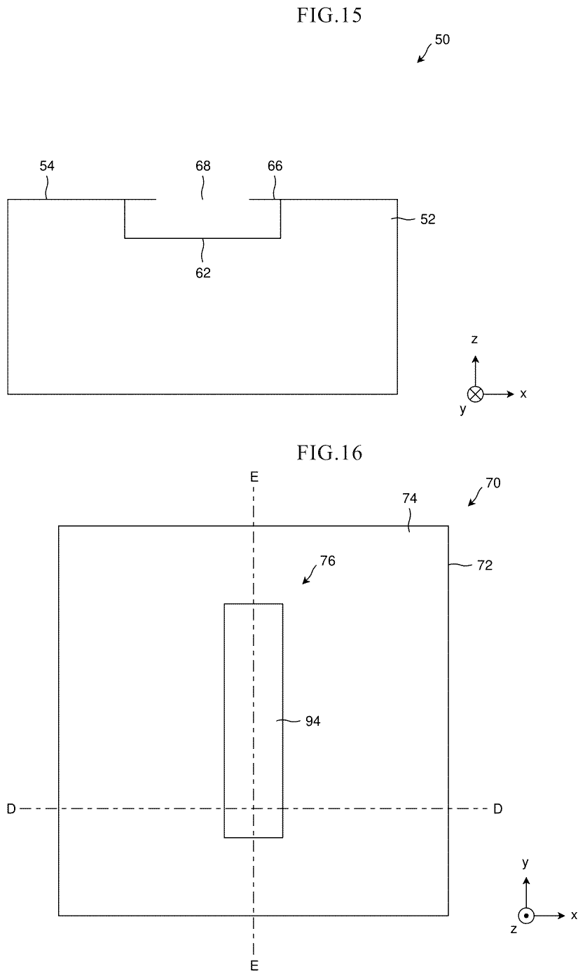

A state resulting from the opening of the hole 68 in the lid portion 66 is illustrated in FIG. 14 and FIG. 15.

As described above, in the method for marking the semiconductor chip according to the present embodiment, because the hole is opened in the lid portion by the probe needle, a width of the hole becomes at least approximately a diameter of the probe needle. Consequently, the shape change in the marking part between times before and after the marking is large, and recognition of presence or absence of the marking is easy.

Further, the position control in the z direction does not have to be highly precise. In the present embodiment, because it is sufficient that the hole is opened even when the position in the z direction is somewhat changed, the position control in the z direction does not have to be highly precise.

Further, when a semiconductor chip is manufactured by using the method for marking the semiconductor chip according to the present embodiment, the semiconductor chip can be obtained which provides the above effects.

### Fourth Embodiment

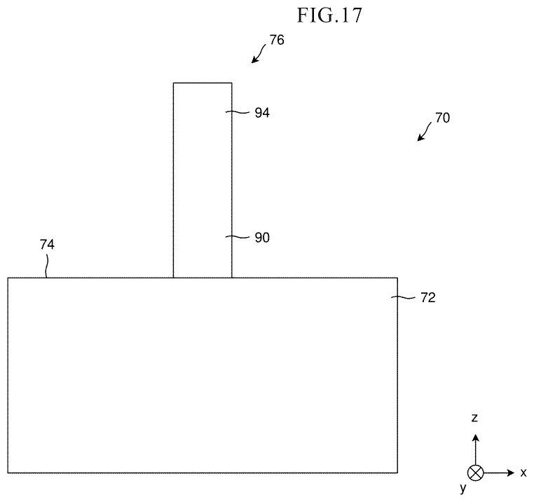

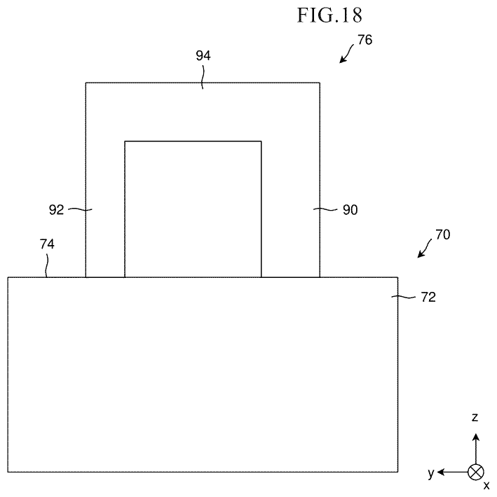

A semiconductor chip 70 according to the present embodiment is illustrated in FIG. 16 to FIG. 18. Here, differences from the first embodiment will mainly be described. FIG. 16 is a top view of the semiconductor chip 70, and FIG. 17 is a cross-sectional view taken along line D-D in FIG. 16. FIG. 18 is a cross-sectional view taken along line E-E in FIG. 16.

A recognition pattern 76 is formed on a surface 74 of a semiconductor substrate 72. The recognition pattern 76 has a first bridge pier 90 and a second bridge pier 92, which protrude from the surface 74 of the semiconductor substrate 72, and a bar portion 94, which connects together upper portions of the first bridge pier 90 and the second bridge pier 92. The first bridge pier 90 is thicker than the second bridge pier 92.

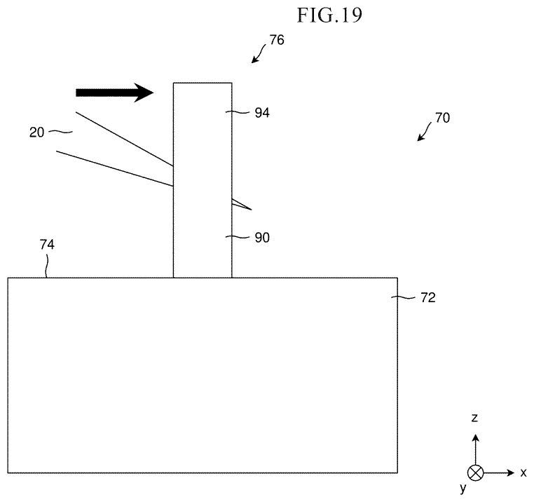

In a method for performing marking in the present embodiment, as illustrated in FIG. 19, the probe needle 20 is moved in a direction parallel to the surface 74 of the semiconductor substrate 72, and the bar portion 94 is thereby pushed. By pushing the bar portion 94, the second bridge pier 92 is detached from the surface 74 of the semiconductor substrate 72. Because the second bridge pier 92 is thinner than the first bridge pier 90, not the first bridge pier 90 but the second bridge pier 92 is detached. In addition, the recognition pattern 76 is rotated around the first bridge pier 90 as a center when seen in the z direction, and the marking is thereby performed.

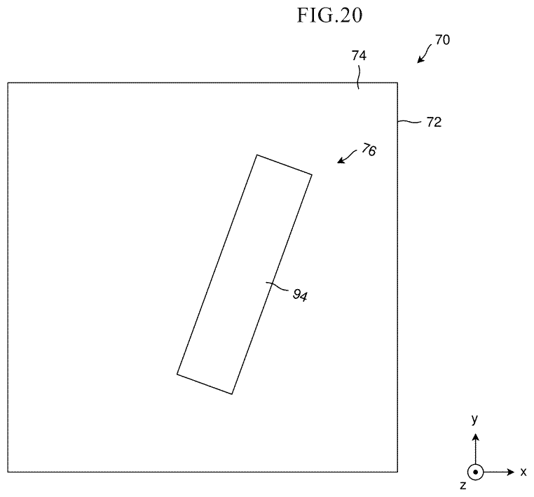

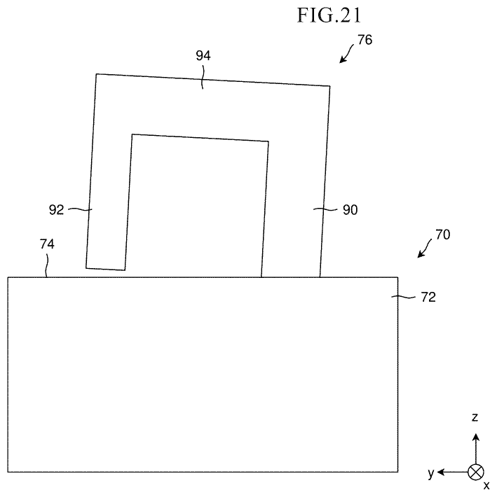

A state resulting from the rotation of the recognition pattern 76 is illustrated in FIG. 20 and FIG. 21.

As described above, in the method for marking the semiconductor chip according to the present embodiment, the recognition pattern is rotated between times before and after the marking. Consequently, the shape change in the marking part between times before and after the marking is large, and recognition of presence or absence of the marking is easy.

Further, the position control in the z direction does not have to be highly precise. In the present embodiment, because it is sufficient that the bar portion 94 can be pushed by the probe needle even when the position in the z direction is somewhat changed, the position control in the z direction does not have to be highly precise.

Further, when a semiconductor chip is manufactured by using the method for marking the semiconductor chip according to the present embodiment, the semiconductor chip can be obtained which provides the above effects.

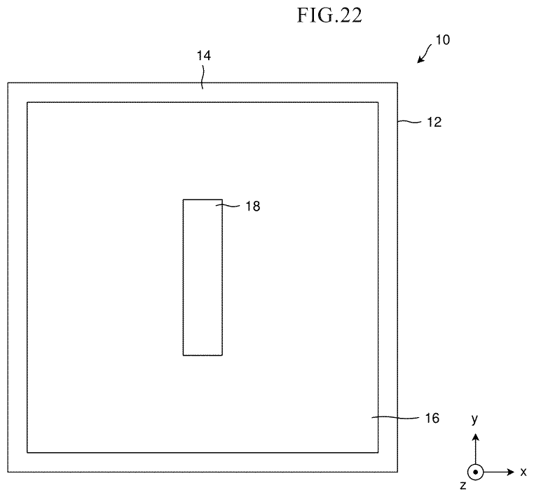

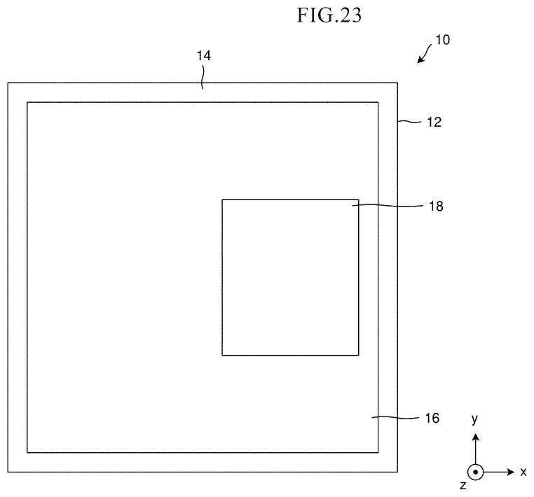

In all of the above embodiments, by forming a recognition pad, the shape change between times before and after the marking may be caused to occur only in the recognition pad when seen in the z direction. For example, in a case where a recognition pad 16 is applied to the first embodiment, states at times before and after the marking become like FIG. 22 and FIG. 23. As described above, when the shape change is limited to an inside of the recognition pad, because a visual recognition region can be fixed to the inside of the recognition pad in performing recognition by eyes or a camera, recognition becomes easy. Further, as the first, second, and fourth embodiments, in a case where the position of the recognition pattern changes, a case where the size of the recess portion becomes larger, and so forth, because those changes can be confirmed while a position or a size of the recognition pad is set as a reference, recognition becomes easy.

Further, in all of the embodiments, the size of the marking part is typically approximately 50 to 100 μm. For example, in the first embodiment, Y of the recognition pattern 18 is approximately 50 to 100 μm. In the second embodiment, the length of one side of the recess portion 42 as seen in the z direction is approximately 50 to 100 μm. In the third embodiment, the length of one side of the lid portion 66 as seen in the z direction is approximately 50 to 100 μm. In the fourth embodiment, the length of the bar portion 94 as seen in the z direction is approximately 50 to 100 μm.

### REFERENCE SIGNS LIST

10,30,50,70 semiconductor chip, 12,32,52,72 semiconductor substrate, 14,34,54,74 surface, 16 recognition pad, 18,76 recognition pattern, 20 probe needle, 42,62 recess portion, 44 edge, 66 lid portion, 68 hole, 90 first bridge pier, 92 second bridge pier, 94 bar portion

1. A method for marking a semiconductor chip, the semiconductor chip including a semiconductor substrate, wherein
in the semiconductor chip, a recognition pattern protruding from a surface is formed on the surface of the semiconductor substrate, and
marking is performed by causing the recognition pattern to fall by a probe needle.

2. The method for marking a semiconductor chip according to claim 1,
wherein
the recognition pattern is a rectangular cuboid,
a direction perpendicular to the surface is set as a z direction,
between two orthogonal sides in a plane of the rectangular cuboid, the plane being perpendicular to the z direction, a direction of a short side is set as an x direction,
when lengths of the rectangular cuboid in the x direction and the z direction are respectively set as X and Z, Z≥2*X, and
when the recognition pattern is caused to fall, a side surface of the rectangular cuboid, the side surface being perpendicular to the x direction, is pushed by the probe needle.

3. A method for marking a semiconductor chip, the semiconductor chip including a semiconductor substrate, wherein
in the semiconductor chip, a recess portion is formed in a surface of the semiconductor substrate, and
marking is performed by pushing an edge of the recess portion by a probe needle and shaving a part of the edge.

4. A method for marking a semiconductor chip, the semiconductor chip including a semiconductor substrate, wherein
in the semiconductor chip, a recess portion and a lid portion covering the recess portion are formed in a surface of the semiconductor substrate, and
marking is performed by opening a hole in the lid portion by a probe needle.

5. A method for marking a semiconductor chip, the semiconductor chip including a semiconductor substrate, wherein
in the semiconductor chip, a recognition pattern is formed on a surface of the semiconductor substrate, the recognition pattern having a first bridge pier and a second bridge pier, which protrude from the surface, and a bar portion, which connects together upper portions of the first bridge pier and the second bridge pier,
the first bridge pier is thicker than the second bridge pier, and
marking is performed by detaching the second bridge pier from the surface by pushing the bar portion by a probe needle which is moved in a direction horizontal to the surface and further by rotating the recognition pattern around the first bridge pier as a center when the semiconductor chip is seen in a direction perpendicular to the surface.

6. The method for marking a semiconductor chip according to claim 1, wherein
a recognition pad is formed on the surface, and
when the semiconductor chip is seen in a direction perpendicular to the surface, a shape change between times before and after the marking occurs only in the recognition pad.

7. A method for manufacturing a semiconductor chip, wherein
the semiconductor chip is manufactured by using the method for marking a semiconductor chip according to claim 1.

8. A semiconductor chip comprising:
a semiconductor substrate; and
a recognition pattern protruding from a surface on the surface of the semiconductor substrate, wherein
the recognition pattern is a rectangular cuboid,
a direction perpendicular to the surface is set as a z direction,
between two orthogonal sides in a plane of the rectangular cuboid, the plane being perpendicular to the z direction, a direction of a short side is set as an x direction, and
when lengths of the rectangular cuboid in the x direction and the z direction are respectively set as X and Z, Z≥2*X.

9. A semiconductor chip comprising:
a semiconductor substrate; and
a first bridge pier and a second bridge pier, which protrude from a surface, and a bar portion, which connects together upper portions of the first bridge pier and the second bridge pier, on the surface of the semiconductor substrate, wherein
the first bridge pier is thicker than the second bridge pier.

10. The method for marking a semiconductor chip according to claim 3, wherein
a recognition pad is formed on the surface, and
when the semiconductor chip is seen in a direction perpendicular to the surface, a shape change between times before and after the marking occurs only in the recognition pad.

11. A method for manufacturing a semiconductor chip, wherein
the semiconductor chip is manufactured by using the method for marking a semiconductor chip according to claim 3.

12. The method for marking a semiconductor chip according to claim 4, wherein
a recognition pad is formed on the surface, and
when the semiconductor chip is seen in a direction perpendicular to the surface, a shape change between times before and after the marking occurs only in the recognition pad.

13. A method for manufacturing a semiconductor chip, wherein
the semiconductor chip is manufactured by using the method for marking a semiconductor chip according to claim 4.

14. The method for marking a semiconductor chip according to claim 5, wherein
a recognition pad is formed on the surface, and
when the semiconductor chip is seen in a direction perpendicular to the surface, a shape change between times before and after the marking occurs only in the recognition pad.

15. A method for manufacturing a semiconductor chip, wherein
the semiconductor chip is manufactured by using the method for marking a semiconductor chip according to claim 5.
